(19) United States
(12) Patent Application Publication
(10) Pub. No.: US 2025/0257495 A1
(43) Pub. Date: Aug. 14, 2025

(54) BI-DIRECTIONAL HEATING OF A SILICON CHARGE

(71) Applicant: GlobalWafers Co., Ltd., Hsinchu (TW)

(72) Inventors: William L. Luter, St. Charles, MO (US); Richard J. Phillips, St. Peters, MO (US)

(21) Appl. No.: 19/047,247

(22) Filed: Feb. 6, 2025

Related U.S. Application Data
(60) Provisional application No. 63/551,147, filed on Feb. 8, 2024.

(51) Int. Cl. C30B 15/14; C30B 29/06

(52) U.S. Cl. CPC C30B 15/14; C30B 29/06

(57) ABSTRACT

Bi-directional heating of a charge of solid silicon in a crucible assembly of an ingot puller apparatus is disclosed. The ingot puller apparatus may include an elliptical reflector disposed above the charge during meltdown. In some embodiments, an upper heater is disposed above the charge and heat from the upper heater is reflected down toward the charge by the elliptical reflector.

### CROSS-REFERENCE TO RELATED APPLICATIONS

This application claims the benefit of U.S. Provisional Patent Application No. 63/551,147, filed Feb. 8, 2024, which is incorporated herein by reference in its entirety.

### TECHNICAL FIELD

The field of the disclosure relates to bi-directional heating of a charge of solid silicon in a crucible assembly of an ingot puller apparatus.

### BACKGROUND

Single crystal silicon, which is the starting material for most processes for the fabrication of semiconductor electronic components, is commonly prepared by the so-called Czochralski (“Cz”) method. According to the Czochralski method, solid polycrystalline silicon (“polysilicon”) is charged to a crucible and melted. A seed crystal is brought into contact with the molten silicon and a single crystal ingot is grown by slow extraction.

Conventional methods for melting the charge of solid silicon involve bringing the crucible into proximity with the bottom heater and powering the bottom heater and side heater to melt the charge. Melting occurs by heating through the susceptor and crucible. Heat transfer occurs by radiation from the bottom and side heaters. This radiation is incident on the susceptor which supports the crucible. The heat conducts through the crucible and is transferred across a small gap into the crucible. Energy transfers through the crucible wall by conduction or radiation. Depending on the transparency of the crucible, some energy is scattered on the outer surface and reflected back into the susceptor. Once the energy passes through the crucible, it becomes incident on the solid silicon and raises the temperature and converts the solid polysilicon into liquid silicon through melting.

The arrangement of materials and surfaces in the ingot puller apparatus are characterized by built in inefficiencies and heat losses which are compensated by increasing the power of the heater(s) to effect a relatively quick meltdown. This increase in power promotes reaction between graphite and silica surfaces, resulting in higher erosion rates of the materials. Increased temperatures also cause higher defectivity in the crucible and causes bubbles to expand. Higher heating temperatures cause non-uniform heating of the crucible sidewall which affects the surface devitrification on the crucible and increases silicon defectivity. This defectivity in the silicon is manifested through increased loss of zero dislocation structure during the ingot growth cycle and increased air pocket formation.

A need exists for ingot puller apparatus and methods for producing a single crystal silicon ingot which increase the efficiency at which the silicon charge is melted.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to an ingot puller apparatus for manufacturing a single crystal silicon ingot. The ingot puller apparatus includes a crucible assembly for holding a silicon melt. A crystal puller housing defines a growth chamber for pulling a silicon ingot from the silicon melt. The crucible assembly is disposed within the growth chamber. A side heater is disposed radially outward to the crucible assembly. An elliptical reflector is disposed above the crucible assembly. The elliptical reflector defines a reflector chamber. An upper heater is disposed within the reflector chamber.

Another aspect of the present disclosure is directed to an ingot puller apparatus for manufacturing a single crystal silicon ingot. The ingot puller apparatus includes a crucible assembly for holding a silicon melt. A crystal puller housing defines a growth chamber for pulling a silicon ingot from the silicon melt. The crucible assembly is disposed within the growth chamber. A single elliptical reflector is disposed above the crucible assembly. The single elliptical reflector defines a reflector chamber. An upper heater is disposed within the reflector chamber.

Yet another aspect of the present disclosure is directed to a method for preparing a single crystal silicon ingot in an ingot puller apparatus. The ingot puller apparatus includes a crucible assembly for holding a melt of silicon, a growth chamber for pulling a silicon ingot from the melt along a pull axis, a side heater disposed radially outward to the crucible assembly, and a pull mechanism for raising and lowering the crucible assembly during crystal growth relative to the pull axis. A charge of solid silicon is added to the crucible assembly. An elliptical reflector is connected to the pull mechanism. The pull mechanism is operated to lower the elliptical reflector toward the charge of solid silicon. An upper heater is powered to direct radiant heat toward the elliptical reflector. The elliptical reflector reflects radiant heat into the charge of solid silicon to melt the silicon charge and form a silicon melt. The elliptical reflector is removed from the ingot puller apparatus. A seed crystal is connected to the pull mechanism. The pull mechanism is operated to lower the seed crystal to contact the silicon melt. The pull mechanism is operated to raise the seed crystal to cause a silicon ingot to be withdrawn from the melt.

Yet a further aspect of the present disclosure is directed to an ingot puller apparatus for manufacturing a single crystal silicon ingot. The ingot puller apparatus includes a crucible assembly for holding a silicon melt. A crystal puller housing defines a growth chamber for pulling a silicon ingot from the silicon melt. The crucible assembly is disposed within the growth chamber. A side heater is disposed radially outward to the crucible assembly. An elliptical reflector is disposed above the crucible assembly. The elliptical reflector defines a reflector chamber. The elliptical reflector is torus-shaped and has a central opening.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of an ingot puller apparatus having a crucible with a silicon charge therein;

FIG. 2 is a cross-section view of the ingot puller apparatus with an elliptical reflector and upper heater connected to the pull mechanism;

FIG. 3 is a cross-section view of the ingot puller apparatus after melt-down and before contacting the melt with a seed crystal;

FIG. 4 is a cross-section view of the ingot puller apparatus during ingot growth;

FIG. 5 is a cross-section view of the ingot puller apparatus with the ingot being fully formed;

FIG. 6 includes schematic views of the ingot puller apparatus during meltdown; and

FIG. 7 is a cross-section view of another embodiment of an ingot puller apparatus with a torus-shaped elliptical reflector and upper heater.

Corresponding reference characters indicate corresponding parts throughout the drawings.

### DETAILED DESCRIPTION

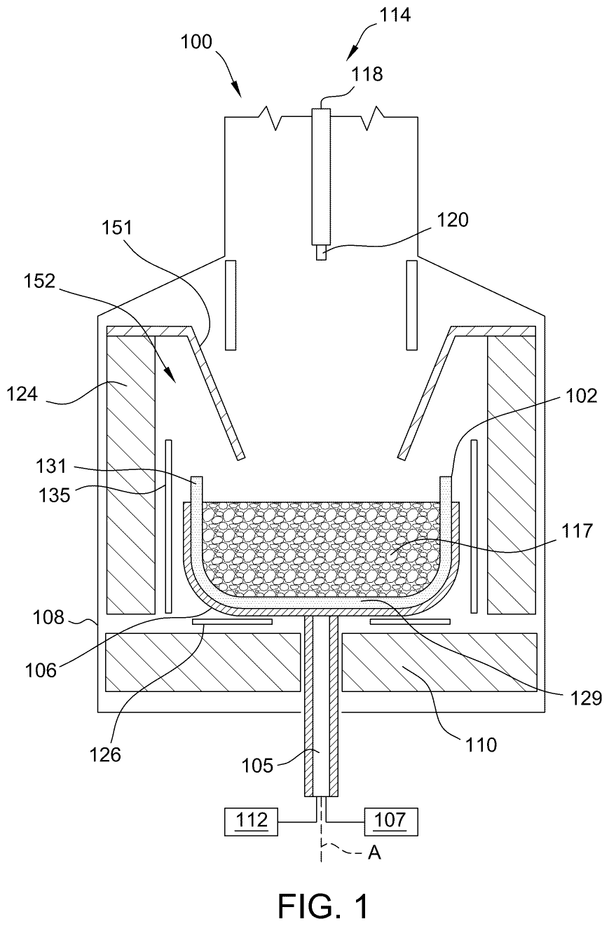

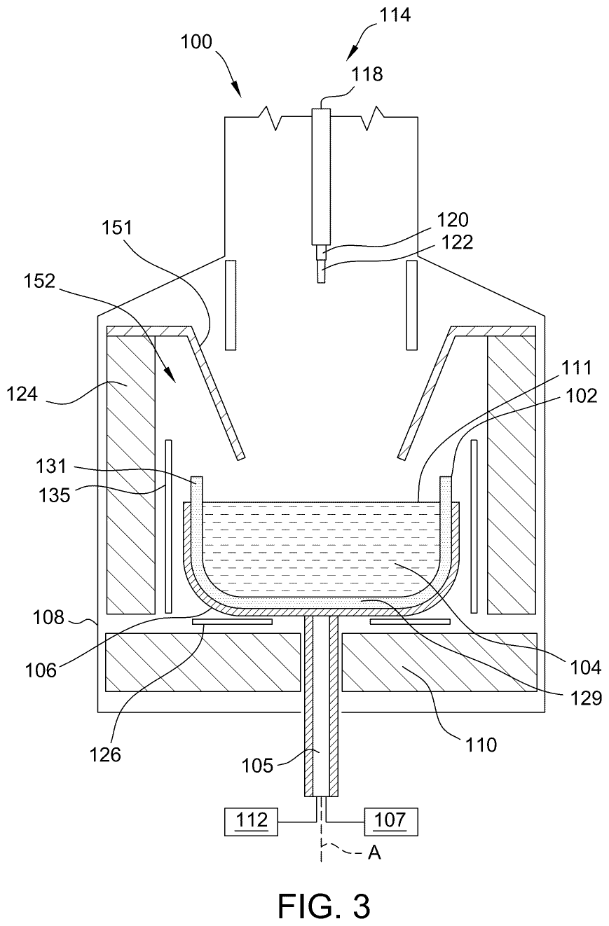

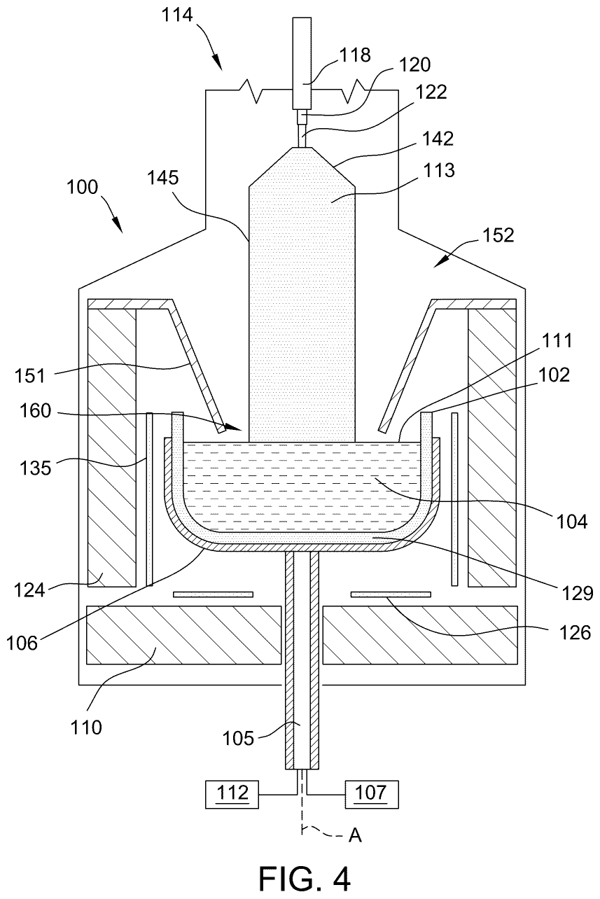

Provisions of the present disclosure relate to ingot puller apparatus that include an elliptical reflector disposed above the crucible assembly for meltdown of solid silicon to prepare a silicon melt used during the Czochralski process. An ingot puller apparatus (or more simply “ingot puller”) is indicated generally at “100” in FIGS. 1-5. The ingot puller apparatus 100 includes a crucible assembly 102 for holding a melt 104 (FIG. 3) of semiconductor or solar-grade material, such as silicon, supported by a susceptor 106. The ingot puller apparatus 100 includes a crystal puller housing 108 that defines a growth chamber 152 for pulling a silicon ingot 113 (FIG. 4) from the melt 104 along a pull axis A.

The crucible assembly 102 includes a floor 129 and a sidewall 131 that extends upward from the floor 129. The sidewall 131 is generally vertical. The floor 129 includes the curved portion of the crucible assembly 102 that extends below the sidewall 131. Within the crucible assembly 102 is a silicon melt 104 having a melt surface 111 (i.e., melt-ingot interface).

The susceptor 106 is supported by a shaft 105. The susceptor 106, crucible assembly 102, shaft 105 and ingot 113 (FIG. 4) have a common longitudinal axis A or “pull axis” A.

The ingot puller apparatus 100 includes a pull mechanism 114 for growing and pulling an ingot 113 from the melt 104. Pull mechanism 114 includes a pulling cable 118, a seed holder or chuck. One end of the pulling cable 118 is connected to a pulley (not shown) or a drum (not shown), or any other suitable type of lifting mechanism, for example, a shaft, and the other end is connected to the chuck 120. For ingot growth, a seed crystal 122 is connected to the chuck 120 and the seed crystal 122 is lowered to contact the melt 104. The pull mechanism 114 is operated to cause the seed crystal 122 to rise. This causes a single crystal ingot 113 (FIG. 4) to be pulled from the melt 104.

During heating and crystal pulling, a crucible drive unit 107 (e.g., a motor) rotates the crucible assembly 102 and susceptor 106. A lift mechanism 112 raises and lowers the crucible assembly 102 along the pull axis A during the growth process. For example, as shown in FIG. 1, the crucible assembly 102 may be at a lowest position (near the bottom heater 126) in which a charge 117 (FIG. 1) of solid polycrystalline silicon previously added to the crucible assembly 102 is melted. After meltdown, crystal growth commences by contacting the melt 104 (FIG. 3) with the seed crystal 122 and lifting the seed crystal 122 by the pull mechanism 114. The crucible assembly 102 may be raised a distance from its lowest position before the melt 104 is contacted with the seed crystal 122 (i.e., raised to a “seed-dip position”). As the ingot 113 grows, the silicon melt 104 is consumed and the height of the melt 104 in the crucible assembly 102 decreases. The crucible assembly 102 and susceptor 106 may be raised to maintain the melt surface 111 at or near the same position relative to the ingot puller apparatus 100.

A crystal drive unit (not shown) may also rotate the pulling cable 118 and ingot 113 in a direction opposite the direction in which the crucible drive unit 107 rotates the crucible assembly 102 (e.g., counter-rotation). In embodiments using iso-rotation, the crystal drive unit rotates the pulling cable 118 in the same direction in which crucible drive unit 107 rotates the crucible assembly 102. In addition, the crystal drive unit 107 raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a charge 117 (FIG. 1) of polycrystalline solid silicon, or polysilicon, is charged to the crucible assembly 102. Solid silicon that is used to form the charge 117 may be granular, chunk, chip, or a combination of thereof. The semiconductor or solar-grade material that is introduced into the crucible assembly is melted by heat provided from one or more heaters. The ingot puller apparatus 100 includes bottom insulation 110 and side insulation 124 to retain heat in the puller apparatus 100. In the illustrated embodiment, the ingot puller apparatus 100 includes a bottom heater 126 disposed below the crucible assembly 102 (i.e., below the floor 129). The crucible assembly 102 may be moved to be in relatively close proximity to the bottom heater 126 to melt the polycrystalline solid charge 117 in the crucible assembly 102.

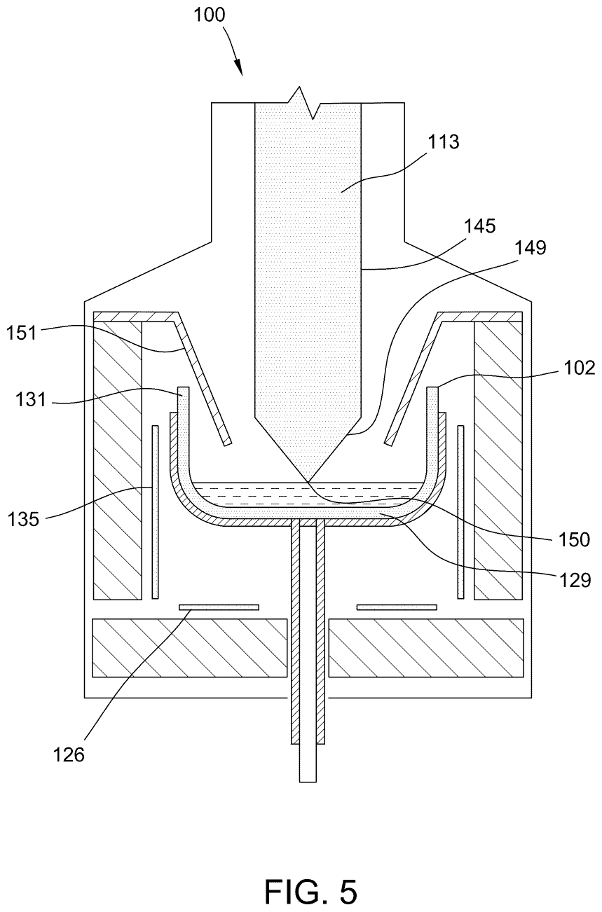

To form the ingot, the seed crystal 122 is contacted with the surface 111 (FIG. 3) of the melt 104. The pull mechanism 114 is operated to pull the seed crystal 122 from the melt 104. Referring now to FIG. 4, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone 149 (FIG. 5) in which the ingot tapers in diameter after the main body 145. When the diameter becomes small enough, the ingot 113 is then separated from the melt 104.

The ingot puller apparatus 100 includes a side heater 135 and a susceptor 106 that encircles the crucible assembly 102 to maintain the temperature of the melt 104 during crystal growth. The side heater 135 is disposed radially outward to the crucible assembly sidewall 131 as the crucible assembly 102 travels up and down the pull axis A (e.g., from the lowest position to the terminal position). The side heater 135 and bottom heater 126 may be any type of heater that allows the side heater 135 and bottom heater 126 to operate as described herein. In some embodiments, the heaters 135, 126 are electrical resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 such that the ingot 113 passes through an opening 160 formed by the heat shield 151. The heat shield 151 may be disposed within the crucible assembly 102 during crystal growth (e.g., as shown in the terminal portion of the crucible assembly 102 as shown in FIG. 5). The heat shield 151 is fixed and does not move within the ingot puller apparatus 100.

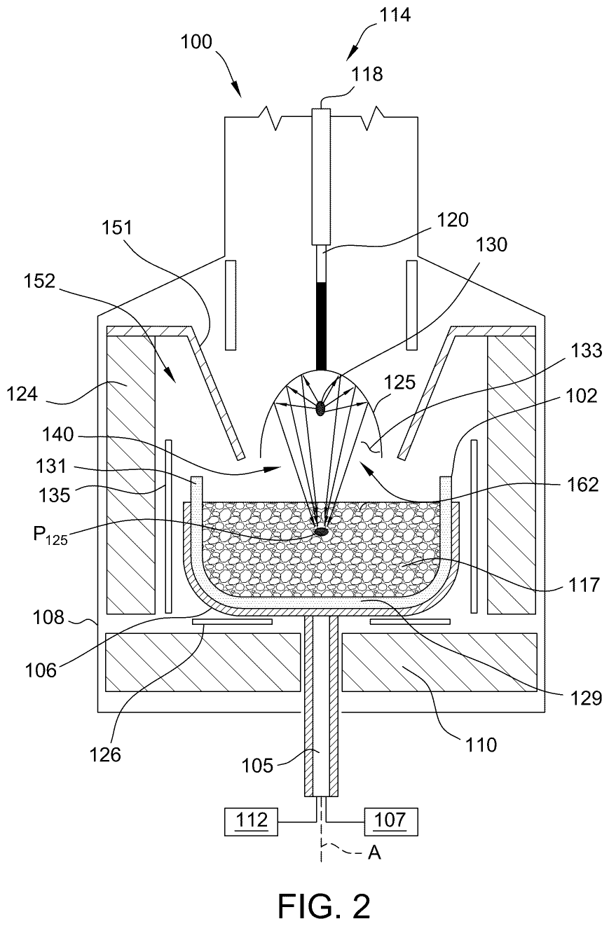

Referring now to FIG. 2, the ingot puller apparatus 100 includes an elliptical reflector 125 that is disposed above the crucible assembly 102 for melting the silicon charge 117. The elliptical reflector 125 defines a reflector chamber 133 within reflector 125. The elliptical reflector 125 is connected to the pull mechanism 114 such as by connecting the reflector 125 to the chuck 120. The elliptical reflector 125 (i.e., a reflector includes a reflective surface with a cross-section defined by two focal points such that the sum of the distances to the two points is the same) may be half an ellipse or may be longer or shorter than half an ellipse (<0.5 length or >0.5 length). In some embodiments (e.g., passive reflector), the length may be <0.5 the length of the full ellipse). In embodiments having active heating, the length may be <0.5 length or >0.5 length the full ellipse length. The elliptical reflector 125 may have a diameter less than the diameter of the opening of the fixed heat shield 151 (e.g., between 50% and 100% or between 75% and 100% of the diameter of the opening 160).

The elliptical reflector 125 may be made of graphite and may be coated with molybdenum, tantalum or hafnium. In some embodiments, the elliptical reflector 125 is an assembly such as a welded quartz assembly having an interior volume with reflective interior coating such as platinum or other coating suitable for high infrared reflection.

In the illustrated embodiment, an upper heater 130 is disposed within the reflector chamber 133. The upper heater 130 is supported by the pull mechanism 114 and may be suspended from the elliptical heat shield 125. The upper heater 130 may be an electrical resistance heater. The upper heater 130 may have any suitable shape (coil, disk, annular, etc.). The upper heater 130 may be made of graphite and may be coated with SiC or hafnia. In other embodiments, the upper heater 130 may be made of tungsten encased with quartz or sapphire glass.

Before ingot growth, the crucible assembly 102 is filled with solid silicon to form the silicon charge 117 (FIG. 1). After the solid silicon charge 117 is added to the crucible assembly 102, the elliptical reflector 125 is connected to the pull mechanism 114 such as by connection to the chuck 120. The pull mechanism 114 is operated to lower the elliptical reflector 125 toward the charge 117 of solid silicon. The upper heater 130 is powered to direct radiant heat 140 downward toward the charge 117 and upward toward the elliptical reflector 125. Radiant heat 140 that is directed toward the elliptical reflector 125 is reflected through an opening 162 down into the charge 117. In addition to powering the upper heater 130, the bottom heater 126 is powered to melt the charge 117 and form the silicon melt 104 (FIG. 3). Optionally, the side heater 135 may be powered with the upper heater 130 and bottom heater 126 to form the silicon melt 104.

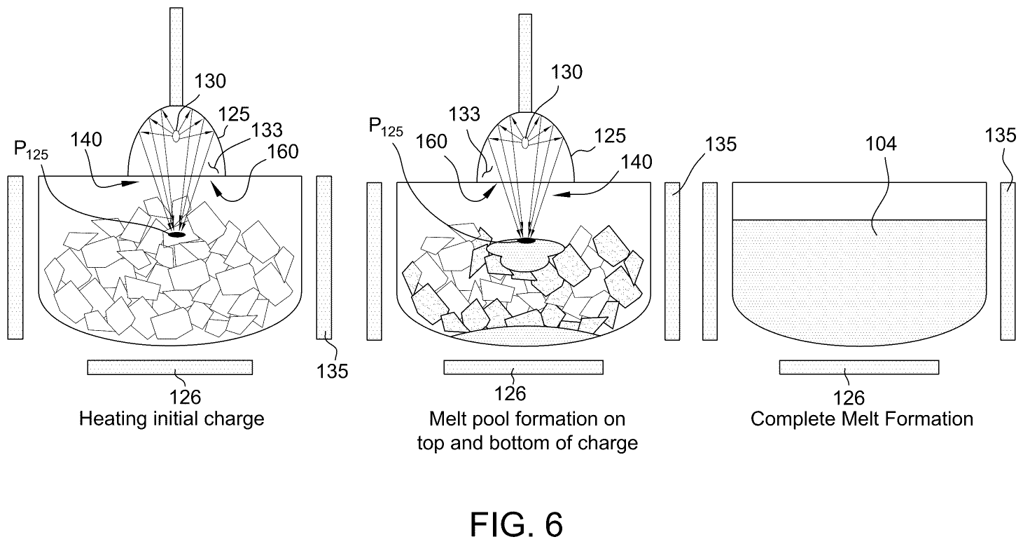

As shown in FIGS. 2 and 6, the elliptical reflector 125 is shaped to focus energy to the upper portion of the silicon charge 117. The reflected radiant heat may converge at or near a focal point P₁₂₅ within the charge 117 (i.e., the focal points and length of the ellipse chosen such that the reflected radiant heat converges at a point P₁₂₅). The focal point P₁₂₅ may be within the upper portion of the silicon charge 117 (i.e., upper 50% or upper 25%).

Once the silicon charge 117 melts to form the silicon melt 104 (or toward the end of meltdown), the elliptical reflector 125 and upper heater 130 are removed from the ingot puller apparatus 100 (e.g., by operating the pull mechanism 114 to lift the reflector 125 and upper heater 130). The elliptical reflector 125 and upper heater 130 may be pulled up into a receiving chamber (not shown) of the ingot puller apparatus 100 and may then be isolated from the lower portion of the ingot puller apparatus. Once the reflector 125 and heater 130 are disconnected from the chuck 120, a seed crystal 122 (FIG. 3) may be connected to the chuck 120. The pull mechanism 114 may be operated to lower the chuck 120 and seed crystal 122 (after the isolation chamber is brought up to temperature) and the seed crystal 122 may be contacted with the melt 104 (FIG. 3) to commence pulling the single crystal silicon ingot 113 (FIG. 4) from the melt 104).

As noted above, in the illustrated embodiment, the upper heater 130 is within the reflector chamber 133. In other embodiments, the upper heater 130 is not disposed within the reflector chamber 133 (i.e., is disposed below the reflector 125). In yet other embodiments, the ingot puller apparatus 100 does not include an upper heater (e.g., the reflector 125 is passive and side and/or bottom heaters 126, 135 are operated with stray heat being reflected back toward the charge 117). In the illustrated embodiments, a single elliptical reflector is shown. In other embodiments, the ingot puller apparatus 100 includes more than one elliptical reflector (e.g., two, three, four or more elliptical reflectors). In some embodiments, the elliptical reflector 125 is water cooled.

The ingot growth process may be a batch process in which polycrystalline silicon is not added to the crucible assembly 102 during ingot growth. In other embodiments, a continuous Czochralski process is used in which polycrystalline silicon is added to the crucible assembly 102 during ingot growth (e.g., with the crucible assembly having one or more fluid barriers that divide the crucible assembly into various zones). In embodiments in which continuous Czochralski is used, the solid silicon may be added to a drop zone in the crucible assembly 102 (e.g., an outer melt zone of the crucible assembly 102 that is below a polysilicon feed tube through which solid silicon is added to the melt 104). The elliptical reflector 125 may be arranged in the ingot puller apparatus such that radiant heat (e.g., from upper heater 130 or from a side heater 135) is directed to the drop zone.

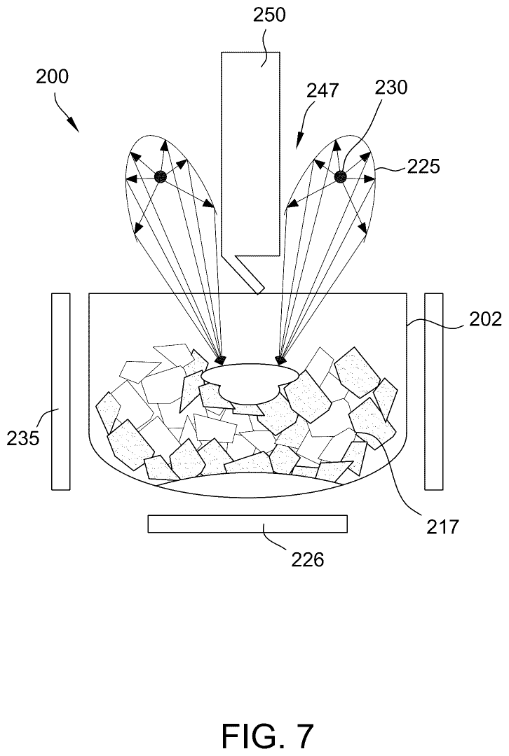

Another embodiment of an ingot puller apparatus 200 is shown in FIG. 7. The components shown in FIG. 7 that are analogous to those of FIGS. 1-6 are designated by the corresponding reference number of FIGS. 1-6 plus “100” (e.g., part 126 becomes 226). The ingot puller apparatus 200 may be identical to the ingot puller apparatus 200 of FIGS. 1-6 with the exception that the ingot puller apparatus includes a torus-shaped elliptical reflector 225. In the illustrated embodiment, the apparatus 100 includes an annular upper heater 230. The torus-shaped elliptical reflector 225 includes a central opening 247. The central opening 247 enables a polysilicon feed tube 250 (which may be made of silicon) to be lowered through the reflector 225 to allow solid polysilicon to be added to the crucible 202. The reflector 230 may be connected to and lowered with the tube 250. The polysilicon feed tube 250 may be lowered and raised by the pull mechanism 114.

Compared to conventional methods for melting a silicon charge, the methods of the present disclosure have several advantages. By heating the silicon charge bi-directionally from below and above the melt, the duration of meltdown may be shortened which increases throughput of the ingot production process. By reflecting heat back toward the charge, efficiency of the meltdown process is improved. Heating the charge from above allows the shape of the charge during meltdown to be changed and prevents or reduces the collapse of the charge into a melt pool that forms below the charge. In embodiments in which the elliptical reflector converges radiant heat to a focal point, heating at the focal point may be more concentrated which promotes meltdown of the silicon. A torus-shaped reflector allows the silicon feed tube to be relatively cooler which protects the relatively fragile feed tube.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller apparatus for manufacturing a single crystal silicon ingot, the ingot puller apparatus comprising:
a crucible assembly for holding a silicon melt;
a crystal puller housing that defines a growth chamber for pulling a silicon ingot from the silicon melt, the crucible assembly being disposed within the growth chamber;
a side heater disposed radially outward to the crucible assembly;
an elliptical reflector disposed above the crucible assembly, the elliptical reflector defining a reflector chamber; and
an upper heater disposed within the reflector chamber.

2. The ingot puller apparatus as set forth in claim 1 wherein the upper heater is an electrical resistance heater.

3. The ingot puller apparatus as set forth in claim 1 wherein the elliptical reflector is the only elliptical reflector disposed above the crucible assembly.

4. The ingot puller apparatus as set forth in claim 1 wherein the upper heater comprises graphite coated with silicon carbide or hafnia.

5. The ingot puller apparatus as set forth in claim 1 wherein the elliptical reflector comprises graphite coated with molybdenum, tantalum or hafnium.

6. The ingot puller apparatus as set forth in claim 1 comprising a bottom heater disposed below the crucible assembly.

7. An ingot puller apparatus for manufacturing a single crystal silicon ingot, the ingot puller apparatus comprising:
a crucible assembly for holding a silicon melt;
a crystal puller housing that defines a growth chamber for pulling a silicon ingot from the silicon melt, the crucible assembly being disposed within the growth chamber;
a single elliptical reflector disposed above the crucible assembly, the single elliptical reflector defining a reflector chamber; and
an upper heater disposed within the reflector chamber.

8. The ingot puller apparatus as set forth in claim 7 wherein the upper heater is an electrical resistance heater.

9. The ingot puller apparatus as set forth in claim 7 wherein the upper heater comprises graphite coated with silicon carbide or hafnia.

10. The ingot puller apparatus as set forth in claim 7 wherein the elliptical reflector comprises graphite coated with molybdenum, tantalum or hafnium.

11. A method for preparing a single crystal silicon ingot in an ingot puller apparatus, the ingot puller apparatus comprising a crucible assembly for holding a melt of silicon, a growth chamber for pulling a silicon ingot from the melt along a pull axis, a side heater disposed radially outward to the crucible assembly, and a pull mechanism for raising and lowering the crucible assembly during crystal growth relative to the pull axis, the method comprising:
adding a charge of solid silicon to the crucible assembly;
connecting an elliptical reflector to the pull mechanism;
operating the pull mechanism to lower the elliptical reflector toward the charge of solid silicon;
powering an upper heater to direct radiant heat toward the elliptical reflector, the elliptical reflector reflecting radiant heat into the charge of solid silicon to melt the silicon charge and form a silicon melt;
removing the elliptical reflector from the ingot puller apparatus;
connecting a seed crystal to the pull mechanism;
operating the pull mechanism to lower the seed crystal to contact the silicon melt; and
operating the pull mechanism to raise the seed crystal to cause a silicon ingot to be withdrawn from the melt.

12. The method as set forth in claim 11 further comprising powering a bottom heater disposed the crucible assembly while powering the upper heater to melt the silicon charge and form a silicon melt.

13. The method as set forth in claim 12 further comprising powering a side heater disposed radially outward to the crucible assembly while powering the upper heater and bottom heater to melt the silicon charge and form a silicon melt.

14. The method as set forth in claim 11 wherein the elliptical reflector is the only elliptical reflector used to melt the silicon charge and form a silicon melt.

15. The method as set forth in claim 11 wherein the elliptical reflector defines a reflector chamber, the upper heater being disposed within the reflector chamber.

16. The method as set forth in claim 11 wherein the upper heater is a side heater disposed radially outward to the crucible assembly.

17. The method as set forth in claim 11 wherein solid silicon is not added to the melt while withdrawing the single crystal silicon ingot.

18. The method as set forth in claim 11 wherein solid silicon is added to the melt while withdrawing the single crystal silicon ingot, wherein solid silicon is added to a drop zone in the crucible assembly, the elliptical reflector directing radiant heat to the drop zone.

19. An ingot puller apparatus for manufacturing a single crystal silicon ingot, the ingot puller apparatus comprising:
a crucible assembly for holding a silicon melt;
a crystal puller housing that defines a growth chamber for pulling a silicon ingot from the silicon melt, the crucible assembly being disposed within the growth chamber;
a side heater disposed radially outward to the crucible assembly;
an elliptical reflector disposed above the crucible assembly, the elliptical reflector defining a reflector chamber, the elliptical reflector being torus-shaped and having a central opening.

20. The ingot puller apparatus as set forth in claim 19 wherein the elliptical reflector is connected to a polysilicon feed tube for adding a charge of polysilicon to the crucible assembly.
